(19) United States
(12) Patent Application Publication
(10) Pub. No.: US 2014/0029208 A1
(43) Pub. Date: Jan. 30, 2014

(54) COMPONENT-CONTAINING MODULE AND METHOD FOR PRODUCING COMPONENT-CONTAINING MODULE

(71) Applicants: Nozomu Nishimura, Tokyo (JP); Nobuhiro Mikami, Tokyo (JP)

(72) Inventors: Nozomu Nishimura, Tokyo (JP); Nobuhiro Mikami, Tokyo (JP)

(73) Assignee: NEC CORPORATION, Minato-ku, Tokyo (JP)

(21) Appl. No.: 14/110,341

(22) PCT Filed: Apr. 2, 2012
(86) PCT No.: PCT/JP2012/059614

§ 371 Date: Oct. 7, 2013

(30) Foreign Application Priority Data
Apr. 7, 2011 (JP) 2011-085528

(51) Int. Cl. H05K 1/18; H05K 3/30

(52) U.S. Cl. CPC H05K 1/181; H05K 3/30
USPC 361/728; 29/841

(57) ABSTRACT

The present invention pertains to a component-containing module that is: provided with a substrate configured from flat sections and a projecting section, and electronic components mounted on the flat sections and the projecting section; and characterized in that the electronic components mounted on the flat sections are sealed in resin, and the electronic component mounted on the projecting section has an upper part thereof exposed above the resin surface.

### TECHNICAL FIELD

The invention relates to a component-containing module in which a resin seals a substrate on which a plurality of electric components are mounted, and a method for producing the component-containing module.

### BACKGROUND ART

A housing of an electronic device, e.g. a mobile terminal, includes an upper housing and a lower housing which are made of a synthetic resin. Various electric components, e.g. a component-containing module, a display, a battery, are mounted inside the housing.

In these days, a ubiquitous network society has come for real, and the electronic device is highly required to be minimized and be made thinner. The mobile terminal includes the various components, which have different heights, inside the housing thereof Since the housing has to have a size thereof which allows the highest electric component to be housed, it is difficult to make a further thinner mobile terminal.

Patent document 1 describes the electric component module component in which a surface-mounted component, e.g. a condenser, a resister, or a transistor to be mounted on a substrate, is molded in a resin like naphthalene. The structure is described therein, in which an upper part of the transistor which is the tallest mounting component projects from a resin surface, and consequently all the components are lowered.

### PRIOR ART DOCUMENT

### SUMMARY OF THE INVENTION

### Problem to be Solved by the Invention

In the structure described in Patent document 1, a tall electronic component can be exposed from the resin surface. However, when an intended electronic component is exposed on the resin surface, an electronic component which is taller than the mounting component is also exposed from the resin surface. Consequently, there is the problem that a mounting component which does not need to be exposed is exposed from the resin.

An object of the invention is to provide the component-containing module solving the problem.

### Means for Solving the Problem

The component-containing module related to the invention includes a substrate configured from a flat section and a projecting section, and an electronic component mounted on each of the flat section and the projecting section. The electronic component mounted on the flat section is sealed in a resin, and the electronic component mounted on the projecting section has an upper part thereof exposed on a surface of the resin.

### Effect of the Invention

According to the invention, it is possible to expose an intended electronic component from a resin surface.

### BRIEF EXPLANATION ON THE DRAWINGS

FIG. 1 is a cross-sectional view of a component-containing module in a first exemplary embodiment,

FIG. 2 is a cross-sectional view of a component-containing module in a second exemplary embodiment,

FIG. 3 is a cross-sectional view of a component-containing module in a third exemplary embodiment,

FIG. 4 is a process illustrating, in order of process, a method for producing a component-containing module of a fourth exemplary embodiment,

FIG. 5 is a process illustrating, in order of process, a method for producing a component-containing module of the fourth exemplary embodiment,

FIG. 6 is a process illustrating, in order of process, a method for producing a component-containing module of the fourth exemplary embodiment,

FIG. 7 is a process illustrating, in order of process, a method for producing a component-containing module of the fourth exemplary embodiment,

### MODE FOR CARRYING OUT THE INVENTION

A preferable mode for carrying out the invention is described below by using a drawing. Though an exemplary embodiment describes the technically preferable limitation to carry out the invention, the scope of the invention is not limited to the following.

### First Exemplary Embodiment

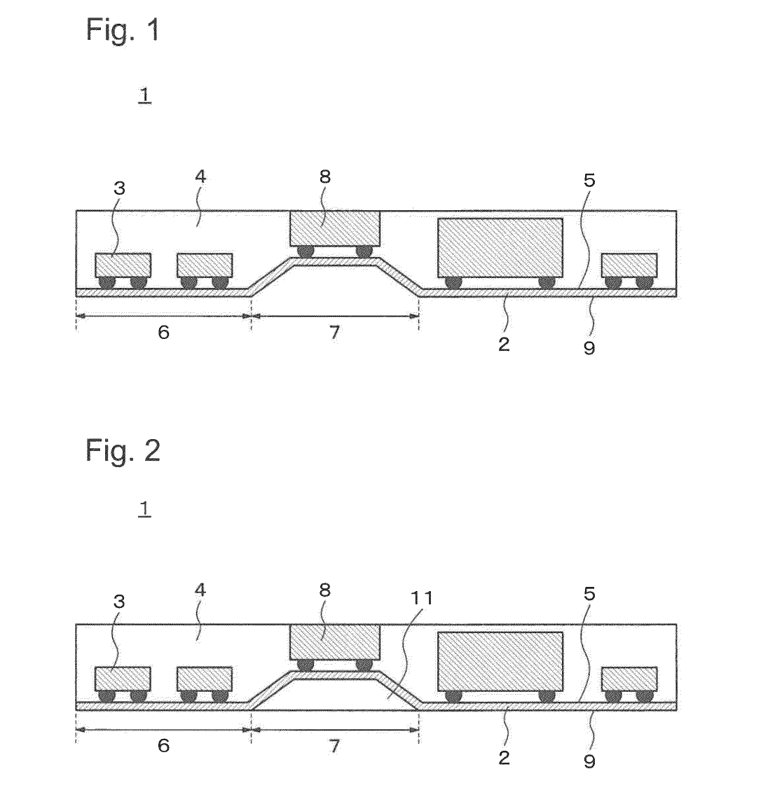

The exemplary embodiment is described in detail referring to the drawing. FIG. 1 is a cross-sectional view of a component-containing module 1 in the exemplary embodiment.

### [Explanation on the Structure]

As shown in FIG. 1, the component-containing module 1 in the exemplary embodiment includes a substrate 2, an electric component 3 and a resin 4.

The substrate 2 is composed of polyimide. A material of the substrate 2 is not limited to the above, and a common material can be employed as the material. As an organic substrate, a substrate which is composed of a glass fiber impregnated with an epoxy resin or a poly-phenylene ether resin, a liquid crystal polymer substrate, or a Teflon (registered trademark) substrate is exemplified. As an inorganic substrate, a glass-ceramic substrate or aluminum substrate is exemplified. Any one of the above substrates may be employed and a metal-based substrate which is integrated with a metal plate, e.g. aluminum or copper, may be employed.

The substrate 2 is a flat plate having two main faces, and a plurality of electric components 3 are placed (mounted) on a flat section 6 of a first face 5 which is one of the main faces. The substrate 2 forms a projecting section 7 which projects in the direction of the first face 5 and which is deformed to be trapezoid-shaped. An electronic component 8 which is intended to be exposed on a surface of a resin 4 is placed (mounted) on the projecting section 7. A height of the projecting section 7 is designed so that an upper part of the electronic component 8 placed on the projecting section 7 becomes higher compared with an upper part of another electric component 3 placed on the flat section 6.

To explain in detail, the projecting section 7 is trapezoid-shaped and is composed of a top face part and a sloop part. The electric component 8 which is intended to be exposed on the surface of the resin 4 is placed on the top face part of the projecting section 7.

The resin 4 seals and molds a plurality of the electric components 3 and the electric component 8 mounted on the first face 5 of the substrate 2. Since the electric component 8, the upper part of which is intended to be exposed on the resin 4, is placed on the top face part of the projecting section 7 of the substrate 2, the upper part of the electronic component 8 is not sealed by the resin 4 and exposes on the surface of the resin 4. The electronic component 3 mounted on the flat section 6 is sealed by the resin 4 together with the upper part thereof.

A fingerprint sensor, a temperature sensor, a humidity sensor, or the like, which functions under the influence of the outside, is supposed as the electric component 8 to be exposed on the resin 4. However, the electric component 8 is not limited to this.

The material of the resin 4 is, for example, an acrylic, an ABS resin (Acrylonitrile-Butadiene-Styrene copolymerization synthetic resin), a Polycarbonate resin, an epoxy resin, a urethane resin, or a silicon resin, which can be used depending on the purpose. In FIG. 1 of the exemplary embodiment, the resin 4 seals all of the first face 5 of the substrate 2.

FIG. 1 shows an example in which the surface of the resin 4 is flattened. However, the surface may be deformed to be a curve shape or a boxlike shape depending on a design of an electric device.

### [Explanation of Operation and Effect]

Next an operation and an effect of the exemplary embodiment are described.

In the structure of Patent document 1, the surface of the resin except an electric component can be wholly lowered by exposing the tall electronic component from the surface of the resin. When the electric component, e.g. a sensor, which is intended to be exposed from the surface of the resin, is mounted, if the electric component is exposed from the surface of the resin, a different electric component which is taller than the electronic component is also exposed from the surface of the resin.

Consequently, when the electronic component which is easy to be influenced from the outside is exposed from the surface of the resin, the electronic component malfunctions or suffers damage due to an outer environment.

In the component-containing module 1 of the exemplary embodiment, the projecting section 7 is formed on the substrate 2, and the electric component 8 which is intended to be exposed on the surface of the resin 4 is placed on the top face part of the projecting section 7. Since the electric component 8 is placed on the top face part of the projecting section 7, the upper part of the electric component 8 can be made higher than the upper part of the electric component 3 mounted on the flat section 6.

As a result, it becomes possible to seal the electric component 3 mounted on the flat section 6 of the substrate 2 without exposing the component 3 on the surface of the resin 4, and to expose the electric component 8 placed on the top face part of the projecting section 7 on the surface of the resin 4. Since the electronic component 8 is placed on the projecting section 7, even a short electronic component can be exposed on the surface of the resin 4.

### Second Exemplary Embodiment

A second exemplary embodiment is described referring to a drawing. FIG. 2 is a drawing in the exemplary embodiment.

### [Explanation on Configuration]

The exemplary embodiment differs from the first exemplary embodiment in that the component-containing module 1 of the exemplary embodiment includes a back resin 11 on a back face of the projecting section 7 in the substrate 2. The other structure and connection relations are the same as those of the first exemplary embodiment, and include the substrate 2, the electronic component 3, and the resin 4.

The substrate 2 is the flat plate having the two main faces, and the plurality of electric components 3 are placed (mounted) on the flat section 6 of the first face 5 which is one of the main faces. The substrate 2 forms the projecting section 7 which projects in the direction of the first face 5 and is deformed to be trapezoid-shaped. The electronic component 8 which is intended to be exposed on the surface of the resin 4 is placed (mounted) on the top face part of the projecting section 7.

A second face 9 which is a main face opposite to the first face 5 of the substrate 2 includes a recess 10 corresponding to the projecting section 7. The recess 10 on the second face 9 of the substrate 2 is sealed by the back resin 11. It is preferable that the back resin 11 is formed on the second face 9 of the substrate 2 so that difference in height between the recess 10 and the flat section 6 is not formed, that is, the second face 9 is flattened.

It is preferable that the back resin 11 placed in the recess 10 of the second face 9 of the substrate 2 is a resin with high stiffness compared with the resin 4 placed on the first surface 5.

### [Explanation of Operation and Effect]

In the component-containing module 1 of the exemplary embodiment, the electric component 8 to be exposed on the surface of the resin 4 is placed on the projecting section 7 formed on the substrate 2. Therefore, it is possible to make the height of the electric component 8 higher than the height of the electric component 3 mounted on the flat section 6, and to make even a short electric component to be exposed on the surface of the resin 4.

The component-containing module 1 includes the back resin 11 in the recess 10 corresponding to the projecting section 7, the recess 10 being formed on the second face 9 of the projecting section 7 of the substrate 2. In the component-containing module 1, the recess 10 on the second face 9 of the substrate 2 is sealed by the back resin 11, and the back resin 11 is formed so that difference in height is not formed with respect to the flat section 6, that is, so that the second face 9 is flattened. Consequently, stiffness of the component-containing module 1 can be increased and warpage of the substrate 2 toward the back face is avoidable.

If the back resin 11 placed in the recess 10 of the second face 9 is made higher stiffness compared with the resin 4 placed on the first surface 5, the electric component 8 placed on the projecting section 7 can be protected against drop inpact.

### Third Exemplary Embodiment

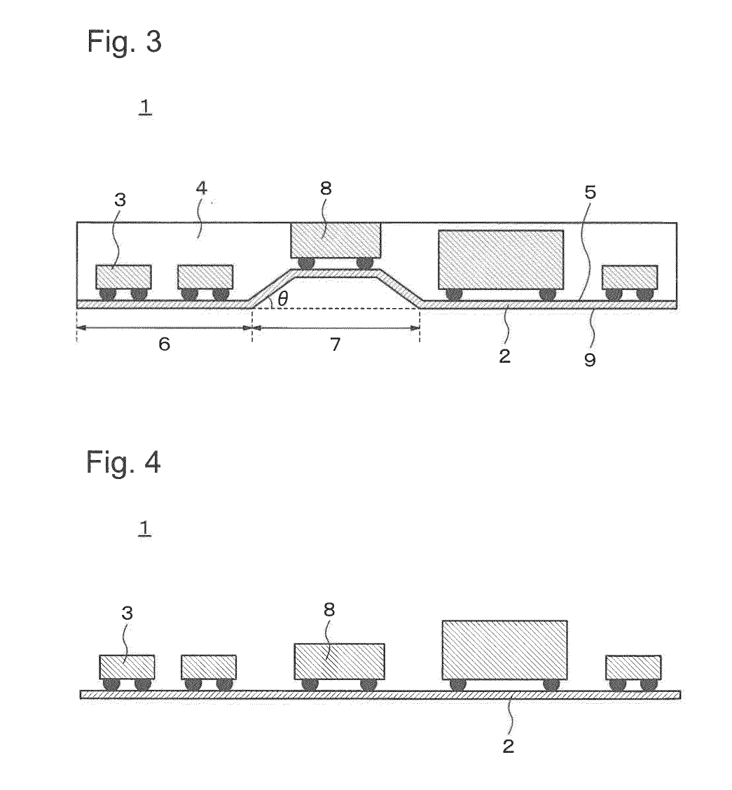

A third exemplary embodiment is described referring to a drawing. FIG. 3 is a drawing in the exemplary embodiment.

### [Explanation on Configuration]

In the exemplary embodiment, as shown in FIG. 3, in the component-containing module 1, an angle between the flat section 6 and the sloop part of the projecting section 7 is 60 degrees or less. The other structure and connection relations are the same as those of the first exemplary embodiment, and include the substrate 2, the electronic component 3, and the resin 4.

The substrate 2 is plate-shaped and includes the two main faces. A plurality of the electronic components 3 are placed (mounted) on the flat section 6 of the first face 5 which is one of the main faces. The substrate 2 forms the projecting section 7 which projects in the direction of first face 5 and which is deformed to be trapezoid-shaped. The electronic component 8 which is intended to be exposed on the surface of the resin 4 is placed (mounted) on the top face part of the projecting section 7.

The projecting section 7 formed on the first face 5 of the substrate 2 is trapezoid-shaped and includes the top face part and the sloop part. The tilt angle θ between the sloop part and the flat section 6 is formed to be 60 degrees or less.

### [Explanation of Operation and Effect]

Suppose that the tilt angle θ between the sloop part of the projecting section 7 and the flat section 6 is 90 degrees which is more than 60 degrees or more, for example. In this case, since the angle between the flat section 6 and the sloop part sharply changes, wiring in the substrate 2 is disconnected.

In the component-containing module 1 of the exemplary embodiment, the sloop part of the projecting section 7 and the flat section forms the tilt angle which is 60 degrees or less. Therefore, without disconnection of the wiring in the substrate 2, the projecting section 7 can be formed on the first face 5 of the substrate 2.

### Fourth Exemplary Embodiment

A fourth exemplary embodiment is described referring to a drawing. FIGS. 4 to 7 are process diagrams illustrating, in order of process, an example of a method of producing the component-containing module 1. The method is described in order of process referring to the drawing.

In Step 1, as shown in FIG. 4, a plurality of electric components 3 and the electronic component 8 to be exposed on the surface of the resin 4 are mounted on the first face 5 of the substrate 2. Next, Step 2 is carried out.

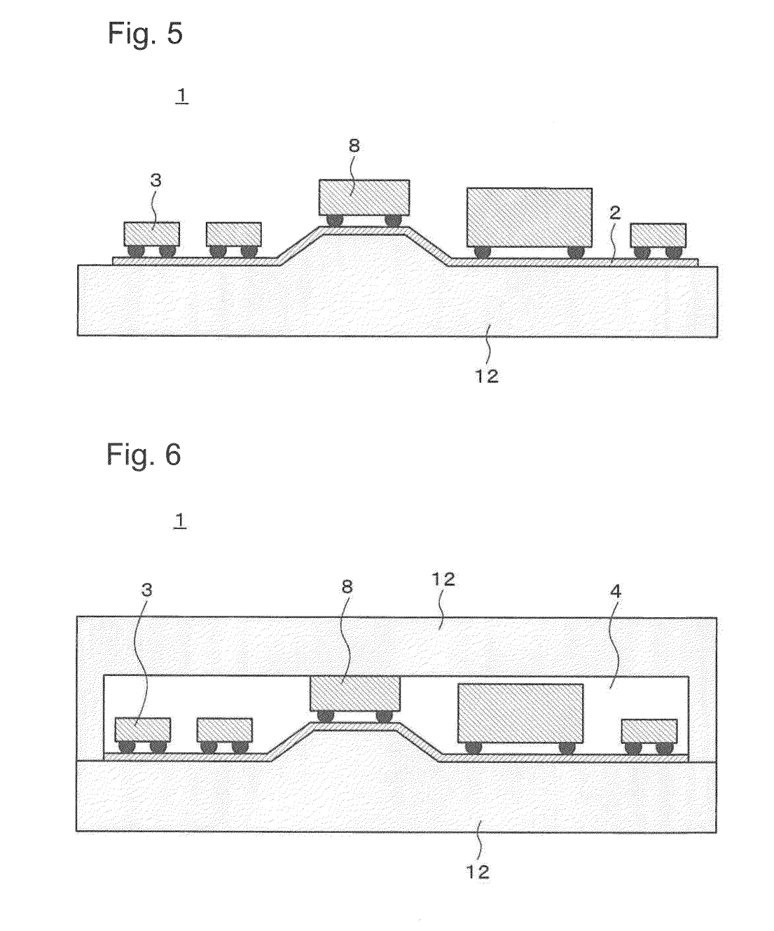

In Step 2, as shown in FIG. 5, after the electric components 3 and 8 are mounted on the first face 5 of the substrate 2, the substrate 2 is placed on a metal mold 12 with a second face 9 thereof down, and is pressed to be deformed. The substrate 2 preferably has a thickness of 0.05 mm to 0.2 mm.

The projecting section 7 is formed so that the electric component 8 which is intended to be exposed on the surface of the resin 4 is placed on the top face part of the projecting section 7. The projecting section 7 is trapezoid-shaped and composed of the top face part and the sloop part. If a thermoplastic resin, e.g. Acrylic, ABS, and PC, is employed as the resin 4 sealing the substrate 2, the temperature of the metal mold 12 is kept around 80 degrees to deform the substrate 2. Next, Step 3 is carried out.

A projecting section is formed on a place on the metal mold 12 which corresponds to the place on which the projecting section 7 is formed on the substrate 2. If the resin is 0.8 mm in thickness and the electric component 8 which is intended to be exposed on the surface of the resin 4 is 0.4 mm in thickness, the height of the projecting section 7 is preferably 0.4 mm or more. If the projecting section 7 with the height of 0.4 mm is formed on the substrate 2, the projecting section with the height of 0.4 mm is formed on the metal mold 12. The projecting section on the metal mold 12 is trapezoid-shaped.

In Step 3, as shown in FIG. 6, the metal mold 12 is set and the resin 4 is injected into the metal mold 12. The resin 4 is injected on the first face 5 of the substrate 2 and on the electric components 3 and 8 placed on the substrate 2.

The resin 4 seals the electric component 3 mounted on a place where the projecting section 7 is not formed, that is, the flat section 6, together with the upper part thereof, and the electric component 8 mounted on the projecting section 7 is formed so that the upper part thereof is exposed. The distance between the upper part of the electronic component 8 and the surface of the resin 4, that is, the distance where the electronic component 8 is exposed, is preferably 0.2 mm or less. Next, Step 4 is carried out.

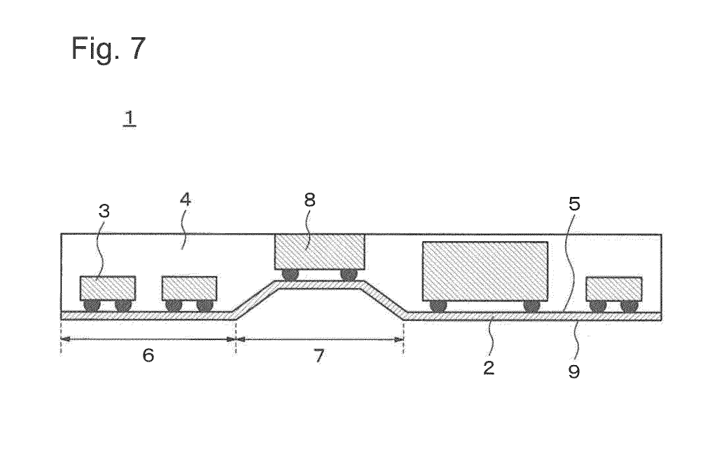

In Step 4, as shown in FIG. 7, the substrate 2 sealed by the resin 4 is taken from the metal mold 12. A decorative sheet or a coating film can be formed in order to improve design of the surface of the resin 4.

In the producing method of the exemplary embodiment, Step 1 is replaced with Step 2 each other. That is, in Step 1, the substrate 2 is placed on the metal mold 12 with the second face 9 thereof down, and the substrate 2 is deformed to form the projecting section 7 by pressing. In Step 2, the plurality of electric components 3 and the electric component 8 to be exposed on the surface of the resin 4 can be mounted on the first face 5 of the substrate 2.

In this case, the electronic component 8 which is intended to be exposed on the surface of the resin 4 is placed on the top face part of the projecting section 7, the plurality of electronic components 3 which is not intended to be exposed on the surface of the resin 4 are placed on the flat section 6.

Though being described based on the above exemplary embodiment, the electronic device and the method of producing the same are not limited to the above descriptions and can includes various type of variations, changes, and improvements.

While having described an invention of the present application referring to the embodiments, the invention of the present application is not limited to the above mentioned embodiments. It is to be understood that to the configurations and details of the invention of the present application, various changes can be made within the scope of the invention of the present application by those skilled in the art.

This application claims priority from Japanese Patent Application No. 2011-085528 filed on Apr. 7, 2011, the contents of which are incorporation herein by reference in their entirety.

### EXPLANATION ON REFERENCE NUMERALS

1 component-containing module
2 substrate
3 electric component
4 resin
5 first face
6 flat section
7 projecting section
8 electric component
9 second face
10 recess
11 back resin
12 metal mold

1. A component-containing module, comprising:
a substrate configured from a flat section and a projecting section; and
an electronic component mounted on each of the flat section and the projecting section, wherein the electronic component mounted on the flat section is sealed in a resin, and the electronic component mounted on the projecting section has an upper part thereof exposed on a surface of the resin.

2. The component-containing module of claim 1, wherein a height of the upper part of the electric component mounted on the projecting section is higher than a height of the upper part of the electric component mounted on the flat section.

3. The component-containing module of claim 1, wherein the projecting section includes a trapezoid-shaped cross-section and includes a sloop part and a top face part, and the electric component exposed on the surface of the resin is placed on the top face part.

4. The component-containing module of claim 1, wherein a face opposite to a face of the substrate on which the electric component is mounted includes a recess corresponding to the projecting section, and a back resin is placed in the recess.

5. The component-containing module of claim 4, wherein the back resin includes higher stiffness compared with the resin sealing the electric component.

6. The component-containing module of claim 4, wherein on the face opposite to the face of the substrate on which the electric component is mounted, the back resin is placed to flatten the recess.

7. The component-containing module of claim 3, wherein the rising angle of the slope part relative to the flat section is 60 degrees or less.

8. The component-containing module of claim 1, wherein the electric component mounted on the projecting section is a fingerprint sensor, a temperature sensor, or a humidity sensor.

9. The component-containing module of claim 1, wherein a material of the resin is an acrylic resin, an ABS resin, a polycarbonate resin, an epoxy resin, a urethane resin, and a silicon resin.

10. A method for producing a component-containing module, comprising:
mounting a plurality of electric components on a substrate;
forming a projecting section in a direction away from a face of the substrate on which the electric components are placed;
placing a resin to seal the electric component mounted on a flat section of the substrate and expose an upper part of the electric component mounted on the projecting section.
